(19) United States
(12) Patent Application Publication
(10) Pub. No.: US 2026/0297393 A1
(43) Pub. Date: Oct. 1, 2026

(54) LAMINATED FILM AND METHOD FOR PRODUCING LAMINATED FILM

(71) Applicant: Resonac Corporation, Tokyo (JP)

(72) Inventors: Miharu KOSHINO, Tokyo (JP); Yukihiro IWANAGA, Tokyo (JP); Keisuke OHKUBO, Tokyo (JP); Naohiro KIMURA, Tokyo (JP); Tomonori HARADA, Tokyo (JP)

(73) Assignee: Resonac Corporation, Tokyo (JP)

(21) Appl. No.: 19/479,510

(22) PCT Filed: Dec. 3, 2024
(86) PCT No.: PCT/JP2024/042752

§ 371 Date: Oct. 28, 2025

(30) Foreign Application Priority Data
Dec. 4, 2023 (JP) 2023-204771

(51) Int. Cl. C09J 7/38; B32B 3/26; B32B 7/12

(52) U.S. Cl. CPC C09J 7/38; B32B 3/266; B32B 7/12; B32B 2307/7376; B32B 2405/00; C09J 2301/208; C09J 2301/302

(57) ABSTRACT

A laminated film includes: an elongated protective film; a plurality of adhesive layers provided on the protective film; a pressure-sensitive adhesive film provided on the plurality of adhesive layers; and a defective-product identifying marking provided on the pressure-sensitive adhesive film at a position corresponding to a defective adhesive layer being an adhesive layer determined to be a defective product among the plurality of adhesive layers. A method for producing a laminated film includes: a preparation step of preparing a raw film; an inspection step of inspecting a plurality of adhesive layers of the raw film; and a marking step of providing a defective-product identifying marking on a pressure-sensitive adhesive film at a position corresponding to a defective adhesive layer being an adhesive layer determined to be a defective product in the inspection step.

### TECHNICAL FIELD

The present disclosure relates to a laminated film and a method for producing the laminated film.

### BACKGROUND ART

In the manufacture of a semiconductor device, a dicing step of dicing a semiconductor wafer into a plurality of semiconductor chips is performed, and thereafter, a bonding step of bonding the diced semiconductor chips to a member to be bonded such as a substrate is performed. Patent Literature 1 describes a laminated film in which a dicing tape, which is used when dicing a semiconductor wafer, and a bonding tape, which is used when bonding a semiconductor chip to a member to be bonded such as a substrate, are integrated. This laminated film is also referred to as a dicing/die bonding integrated film or the like. In addition, Patent Literature 1 also describes that a plurality of adhesive layers functioning as a die bonding tape are provided on a protective film, and that a pressure-sensitive adhesive film functioning as a dicing tape is provided on the plurality of adhesive layers.

### CITATION LIST

### Patent Literature

Patent Literature 1: Japanese Unexamined Patent Publication No. 2005-191322

### SUMMARY OF INVENTION

### Technical Problem

In the laminated film described in Patent Literature 1, since the plurality of adhesive layers are provided on the protective film, the adhesive layers can be attached to a plurality of semiconductor wafers with a single laminated film. However, when an adhesive layer determined to be a defective product is generated due to mixing of foreign matter into the adhesive layer or the like, there is a possibility that a defective semiconductor device is produced. Note that Patent Literature 1 also describes that a mark for identifying the position of each of the plurality of adhesive layers is provided on the pressure-sensitive adhesive film. However, Patent Literature 1 does not disclose a technique for suppressing the occurrence of such a defective semiconductor device.

An object of the present disclosure is to provide a laminated film capable of suppressing the occurrence of a defective semiconductor device, and a method for producing the laminated film.

### Solution to Problem

A laminated film according to one aspect of the present disclosure includes: an elongated protective film; a plurality of adhesive layers provided on the protective film; a pressure-sensitive adhesive film provided on the plurality of adhesive layers; and a defective-product identifying marking provided on the pressure-sensitive adhesive film at a position corresponding to a defective adhesive layer being an adhesive layer determined to be a defective product among the plurality of adhesive layers.

In the laminated film, since a defective-product identifying marking is provided on the pressure-sensitive adhesive film at a position corresponding to a defective adhesive layer, the position of the defective adhesive layer can be specified by detecting the defective-product identifying marking when manufacturing a semiconductor device. Therefore, by attaching the adhesive layers excluding the defective adhesive layer to a semiconductor wafer, the occurrence of a defective semiconductor device can be suppressed.

The pressure-sensitive adhesive film may be provided on the protective film and the plurality of adhesive layers so as to cover the plurality of adhesive layers, and the defective-product identifying marking may be provided on the pressure-sensitive adhesive film. In the laminated film, since the pressure-sensitive adhesive film is provided on the protective film and the plurality of adhesive layers so as to cover the plurality of adhesive layers, and a defective-product identifying marking is provided on the pressure-sensitive adhesive film, the defective-product identifying marking can be detected even after the adhesive layers are peeled from the protective film.

The plurality of adhesive layers may be arranged in a longitudinal direction of the protective film so as to be spaced apart from each other. In the laminated film, since the plurality of adhesive layers are arranged in the longitudinal direction so as to be spaced apart from each other, the adhesive layers can be easily attached to a semiconductor wafer.

When a pair of adhesive layers adjacent to the defective adhesive layer in the longitudinal direction among the plurality of adhesive layers are defined as a first adhesive layer and a second adhesive layer, the defective-product identifying marking may be provided in a region from a first virtual line that passes through a middle between the first adhesive layer and the defective adhesive layer and extends in a width direction orthogonal to the longitudinal direction of the protective film to a second virtual line that passes through a middle between the second adhesive layer and the defective adhesive layer and extends in the width direction. In the laminated film, since the defective-product identifying marking is provided in a region from a first virtual line that passes through a middle between a first adhesive layer and a defective adhesive layer and extends in a width direction to a second virtual line that passes through a middle between a second adhesive layer and the defective adhesive layer and extends in the width direction, the position of the defective adhesive layer can be easily specified from the defective-product identifying marking.

The defective-product identifying marking may be provided in a region from the first virtual line to a third virtual line that passes through a middle of the defective adhesive layer and extends in the width direction. In the laminated film, since the defective-product identifying marking is provided in a region from a first virtual line that passes through a middle between the first adhesive layer and the defective adhesive layer and extends in a width direction orthogonal to a longitudinal direction of the protective film to a third virtual line that passes through a middle of the defective adhesive layer and extends in the width direction, a position of the defective adhesive layer can be easily identified from the defective-product identifying marking. In particular, when the laminated film is conveyed from a first adhesive layer toward a second adhesive layer to detect the defective adhesive layer and the defective-product identifying marking, a deviation between a detection timing of the defective adhesive layer and a detection timing of the defective-product identifying marking can be reduced, such that a position of the defective adhesive layer can be identified more easily from the defective-product identifying marking.

The defective-product identifying marking may be provided in a region from the first virtual line to a fourth virtual line that passes through an end on a side of the first adhesive layer of the defective adhesive layer and extends in the width direction. In the laminated film, since the defective-product identifying marking is provided in a region from a first virtual line that passes through a middle between the first adhesive layer and the defective adhesive layer and extends in a width direction orthogonal to a longitudinal direction of the protective film to a fourth virtual line that passes through an end on a side of the first adhesive layer of the defective adhesive layer and extends in the width direction, a position of the defective adhesive layer can be easily identified from the defective-product identifying marking. In particular, when the laminated film is conveyed from a first adhesive layer toward a second adhesive layer to detect the adhesive layer and the defective-product identifying marking, a deviation between a detection timing of the adhesive layer and a detection timing of the defective-product identifying marking can be reduced, such that a position of the defective adhesive layer can be identified more easily from the defective-product identifying marking.

The defective-product identifying marking may be provided in regions on a side opposite to the defective adhesive layer with respect to a pair of fifth virtual lines that pass through both ends of the defective adhesive layer in a width direction of the protective film orthogonal to the longitudinal direction and extend in the longitudinal direction. In the laminated film, since the defective-product identifying marking is provided in regions on a side opposite to the defective adhesive layer with respect to a pair of fifth virtual lines that pass through both ends of the defective adhesive layer in the width direction and extend in the longitudinal direction, even when the defective-product identifying marking has a thickness, it is possible to suppress the shape of the defective-product identifying marking from being transferred to the adhesive layer.

The defective-product identifying marking may be provided on a non-adhesive-layer region of the pressure-sensitive adhesive film excluding the plurality of adhesive layers. In the laminated film, since the defective-product identifying marking is provided on the non-adhesive-layer region, it is possible to reduce an influence on the adhesive layers caused by providing the defective-product identifying marking.

The defective-product identifying marking may be a filled figure. In the laminated film, since the defective-product identifying marking is a filled figure, the defective-product identifying marking can be easily detected. Moreover, even when identification character information for identifying the adhesive layer is provided on the laminated film, the identification character information and the defective-product identifying marking can be easily distinguished from each other.

An area of the defective-product identifying marking may be 50 mm² or more and 1500 mm² or less. In the laminated film, since the area of the defective-product identifying marking is 50 mm² or more and 1500 mm² or less, the defective-product identifying marking can be easily detected.

A total light transmittance of the defective-product identifying marking may be 0% or more and 10% or less. In the laminated film, since the total light transmittance of the defective-product identifying marking is 0% or more and 10% or less, the defective-product identifying marking can be easily detected.

The defective-product identifying marking may be a code symbol. In the laminated film, since the defective-product identifying marking is a code symbol, by associating information relating to the defective adhesive layer with the code symbol, the information relating to the defective adhesive layer can be obtained when the defective-product identifying marking is detected.

The defective-product identifying marking may be an X mark. In the laminated film, since the defective-product identifying marking is an X mark, the defective-product identifying marking can be easily detected visually.

The defective-product identifying marking may be a slit formed in the laminated film. In the laminated film, since the defective-product identifying marking is a slit formed in the laminated film, the defective-product identifying marking can be easily detected.

An end of the defective-product identifying marking in a longitudinal direction of the protective film may be formed in a curved shape. In the laminated film, since the end of the defective-product identifying marking in the longitudinal direction is formed in a curved shape, it is possible to suppress concentration of stress at the end of the defective-product identifying marking in the longitudinal direction when the laminated film is pulled in the longitudinal direction. Accordingly, it is possible to suppress the laminated film from being broken starting from the end of the defective-product identifying marking in the longitudinal direction.

A length of the slit in a longitudinal direction of the protective film may be 10 mm or more and 100 mm or less. In the laminated film, since the length of the slit in the longitudinal direction is 10 mm or more and 100 mm or less, the defective-product identifying marking can be easily detected, and it is also possible to suppress breakage when the laminated film is pulled in the longitudinal direction.

A width of the slit in a width direction orthogonal to a longitudinal direction of the protective film may be 2 mm or more and 40 mm or less. In the laminated film, since the width of the slit in the width direction is 2 mm or more and 40 mm or less, the defective-product identifying marking can be easily detected, and it is also possible to suppress breakage when the laminated film is pulled in the longitudinal direction.

The defective-product identifying marking may be a hole formed in the laminated film. In the laminated film, since the defective-product identifying marking is a hole formed in the laminated film, it is possible to easily detect the defective-product identifying marking while suppressing breakage when the laminated film is pulled in the longitudinal direction.

One defective-product identifying marking may be provided for one defective adhesive layer. In the laminated film, since one defective-product identifying marking is provided for one defective adhesive layer, it is possible to minimize the number of defective-product identifying markings and suppress contamination of the adhesive layers caused by the defective-product identifying markings.

A plurality of defective-product identifying markings may be provided at different positions for one defective adhesive layer. In the laminated film, since a plurality of defective-product identifying markings are provided at different positions for one defective adhesive layer, a degree of freedom in placing a mark detection unit for detecting the defective-product identifying markings can be increased. Moreover, when semiconductor devices are manufactured in a plurality of facilities having different installation positions of mark detection units for detecting the defective-product identifying markings, versatility of the laminated film can be enhanced by providing the defective-product identifying markings at positions corresponding to the respective facilities.

A method for producing a laminated film according to one aspect of the present disclosure is a method for producing a laminated film for producing any one of the above laminated films, the method including: a preparation step of preparing a raw film including an elongated protective film, a plurality of adhesive layers provided on the protective film, and a pressure-sensitive adhesive film provided on the plurality of adhesive layers; an inspection step of inspecting the plurality of adhesive layers of the raw film; and a marking step of providing a defective-product identifying marking on the pressure-sensitive adhesive film at a position corresponding to a defective adhesive layer being an adhesive layer determined to be a defective product in the inspection step.

In the method for producing a laminated film, since the plurality of adhesive layers of the raw film are inspected and a defective-product identifying marking is provided on the pressure-sensitive adhesive film at a position corresponding to a defective adhesive layer, it is possible to produce a laminated film capable of suppressing occurrence of defective semiconductor devices.

### Advantageous Effects of Invention

According to the present disclosure, the occurrence of a defective semiconductor device can be suppressed.

### BRIEF DESCRIPTION OF DRAWINGS

FIG. 1 is a plan view of a laminated film according to an embodiment.

FIG. 2 is a schematic cross-sectional view taken along line II-II in FIG. 1.

FIG. 3 is a schematic front view showing a state in which the laminated film illustrated in FIG. 1 is wound into a roll.

FIG. 4 is a plan view illustrating an example of a region in which a defective-product identifying marking is provided.

FIG. 5 is a plan view illustrating an example of a region in which a defective-product identifying marking is provided.

FIG. 6 is a plan view illustrating an example of a region in which a defective-product identifying marking is provided.

FIG. 7 is a plan view illustrating an example of a region in which a defective-product identifying marking is provided.

FIG. 8 is a plan view illustrating an example of a position of a defective-product identifying marking.

FIG. 9 is a plan view illustrating an example of a position of a defective-product identifying marking.

FIG. 10 is a plan view illustrating an example of a position of a defective-product identifying marking.

FIG. 11 is a plan view illustrating an example of a position of a defective-product identifying marking.

FIGS. 12(a), 12(b), 12(c), and 12(d) are plan views of defective-product identifying markings for explaining examples of shapes of defective-product identifying markings.

FIGS. 13(a) and 13(b) are plan views of laminated films for explaining examples of shapes of slits serving as defective-product identifying markings.

FIGS. 14(a) and 14(b) are plan views of laminated films for explaining examples of shapes of slits serving as defective-product identifying markings.

FIGS. 15(a) and 15(b) are plan views of laminated films for explaining examples of shapes of holes serving as defective-product identifying markings.

FIGS. 16(a) and 16(b) are plan views of laminated films for explaining examples of shapes of holes serving as defective-product identifying markings.

FIG. 17 is a schematic view illustrating a configuration of an inspection apparatus applied to a method for producing a laminated film according to an embodiment.

### DESCRIPTION OF EMBODIMENTS

Hereinafter, a laminated film and a method for producing the laminated film according to one aspect of the present disclosure will be described in detail with reference to the drawings. Hereinafter, the same or corresponding parts are denoted by the same reference numerals, and redundant description will be omitted.

In the present specification and the claims, the term “layer” includes a structure having a shape partially formed in addition to a structure having a shape formed on the entire surface when observed as a plan view. In addition, the term “step” includes not only an independent step but also a step that cannot be clearly distinguished from other steps as long as the intended purpose of the step is achieved. In addition, a numerical range using “to” indicates a range including numerical values described before and after “to” as a minimum value and a maximum value. Furthermore, in a numerical range described in stages in the present specification, an upper limit value or a lower limit value of the numerical range at one stage may be replaced with an upper limit value or a lower limit value of the numerical range at another stage.

### Laminated Film

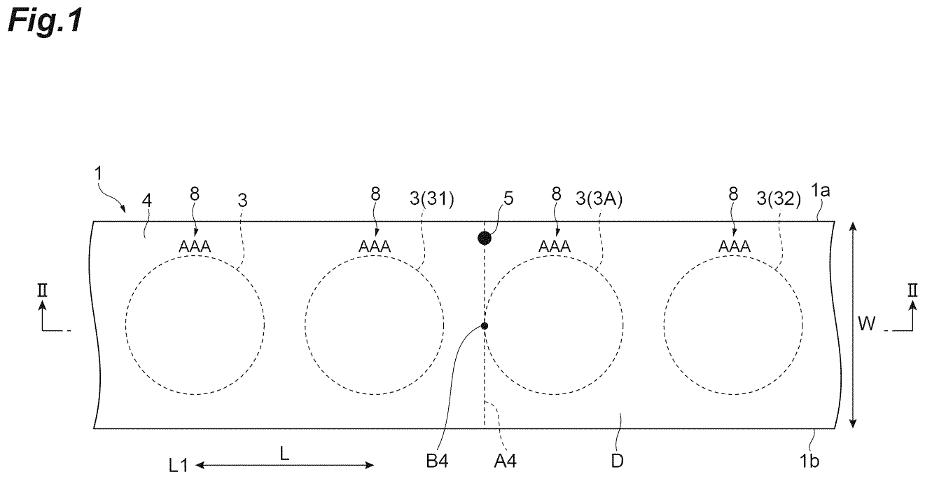

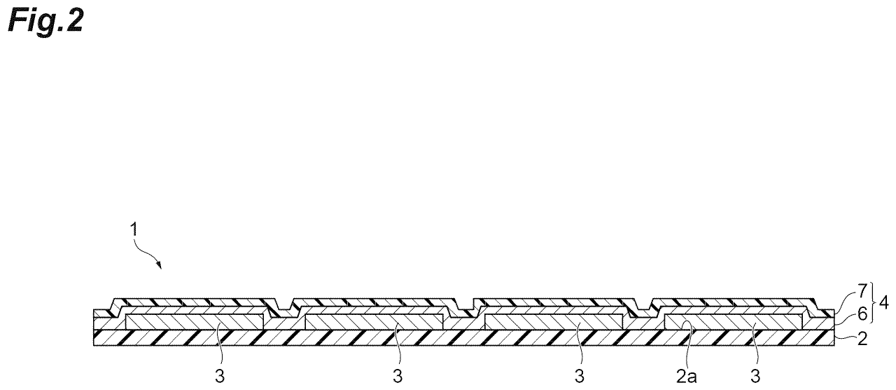

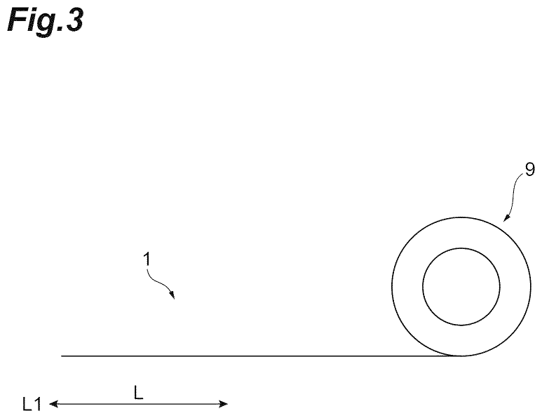

FIG. 1 is a plan view of a laminated film according to an embodiment. FIG. 2 is a schematic cross-sectional view taken along line II-II in FIG. 1. As illustrated in FIGS. 1 and 2, a laminated film 1 according to the present embodiment is, for example, an elongated film used in manufacturing a semiconductor device, such as for fixing a semiconductor wafer in a dicing step and for bonding a semiconductor chip to a member to be bonded such as a substrate in a die bonding step. FIG. 3 is a schematic front view showing a state in which the laminated film illustrated in FIG. 1 is wound into a roll. As illustrated in FIG. 3, the laminated film 1 is generally stored in a state wound into a roll, and at the time of use, it is fed out from a roll 9 according to a required amount. The roll 9 is formed by winding the laminated film 1 into a roll.

As illustrated in FIGS. 1 and 2, the laminated film 1 includes an elongated protective film 2, a plurality of adhesive layers 3, an elongated pressure-sensitive adhesive film 4, and a defective-product identifying marking 5.

Each of the plurality of adhesive layers 3 (hereinafter, also simply referred to as “adhesive layer 3”) is a portion that is attached to a semiconductor wafer. The plurality of adhesive layers 3 are provided on one surface 2a of the protective film 2. The plurality of adhesive layers 3 are arranged in a longitudinal direction L of the protective film 2 at regular intervals so as to be spaced apart from each other. The longitudinal direction L is also an extending direction of the protective film 2. Of the both directions of the longitudinal direction L, a direction in which the laminated film is fed out from the roll 9 (see FIG. 3) is referred to as a first longitudinal direction L1. In addition, the plurality of adhesive layers 3 are disposed at the center in a width direction W orthogonal to the longitudinal direction L of the laminated film 1, and are spaced apart from one end 1a and the other end 1b of the laminated film 1 in the width direction W. The adhesive layer 3 has a circular shape in plan view according to a planar shape of a semiconductor wafer to which it is to be attached. A thickness of the adhesive layer 3 is, for example, 3 μm to 100 μm.

The pressure-sensitive adhesive film 4 is formed to be elongated extending in the longitudinal direction L similarly to the protective film 2, and is provided on the protective film 2 and the plurality of adhesive layers 3 so as to cover the entire one surface 2a of the protective film 2 and the plurality of adhesive layers 3. The pressure-sensitive adhesive film 4 has a two-layer structure including a pressure-sensitive adhesive layer 6 and a base material film 7. The pressure-sensitive adhesive film 4 is disposed so that the pressure-sensitive adhesive layer 6 faces the protective film 2. A thickness of the pressure-sensitive adhesive layer 6 is, for example, 1 μm to 100 μm. A thickness of the base material film 7 is, for example, 30 μm to 150 μm.

The pressure-sensitive adhesive film 4 may be printed with identification character information 8 for identifying the laminated film 1, the adhesive layer 3, or the pressure-sensitive adhesive film 4. The identification character information 8 is composed of linear characters such as alphabets and numerals.

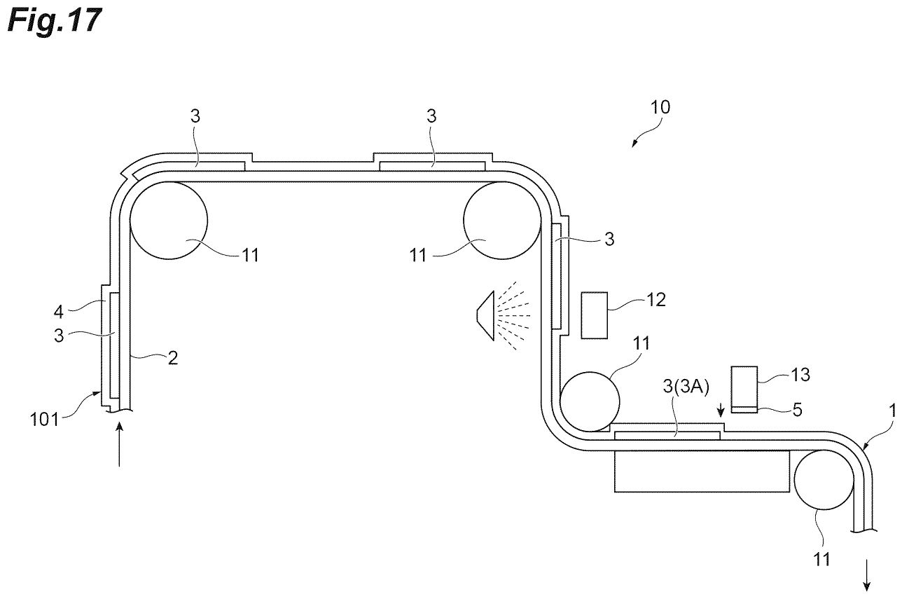

The defective-product identifying marking 5 is a mark for identifying a defective adhesive layer 3A, which is an adhesive layer 3 determined to be a defective product among the plurality of adhesive layers 3. The defective-product identifying marking 5 is provided on the pressure-sensitive adhesive film 4 at a position corresponding to the defective adhesive layer 3A. The defective adhesive layer 3A is, for example, an adhesive layer 3 determined to be a defective product by an inspection apparatus 10 (see FIG. 17) for inspecting the adhesive layer 3. The adhesive layer 3 being a defective product means, for example, a case where foreign matter is mixed into the adhesive layer 3. On the pressure-sensitive adhesive film 4, one defective-product identifying marking 5 may be provided for one defective adhesive layer 3A, or a plurality of defective-product identifying markings 5 may be provided for one defective adhesive layer 3A.

A position corresponding to the defective adhesive layer 3A is a position having a predetermined positional relationship with the defective adhesive layer 3A. A position having a predetermined positional relationship with each adhesive layer 3 serves as a planned marking position (not illustrated). Then, no defective-product identifying marking 5 is provided at planned marking positions corresponding to a defective adhesive layer 3A other than the defective adhesive layer 3A, and the defective-product identifying marking 5 is provided at the planned marking position corresponding to the defective adhesive layer 3A. Therefore, when a plurality of defective adhesive layers 3A are present in the laminated film 1, a positional relationship between the defective adhesive layer 3A and the defective-product identifying marking 5 is the same in all of the defective adhesive layers 3A.

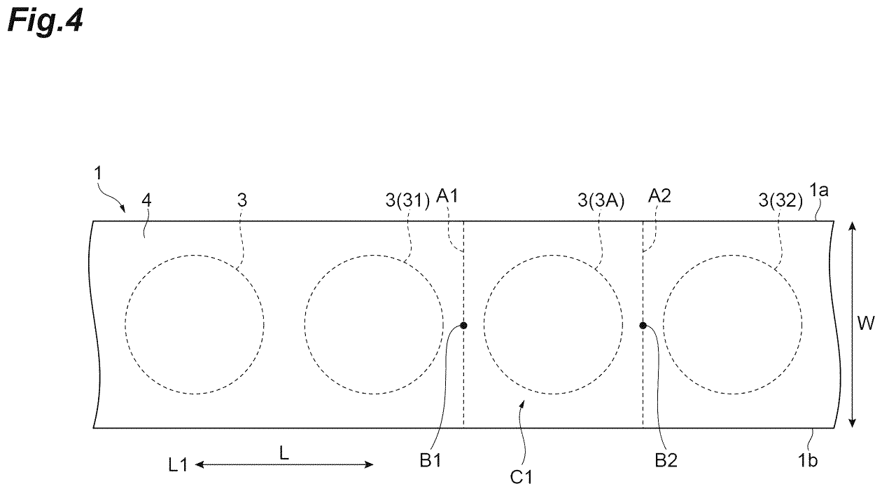

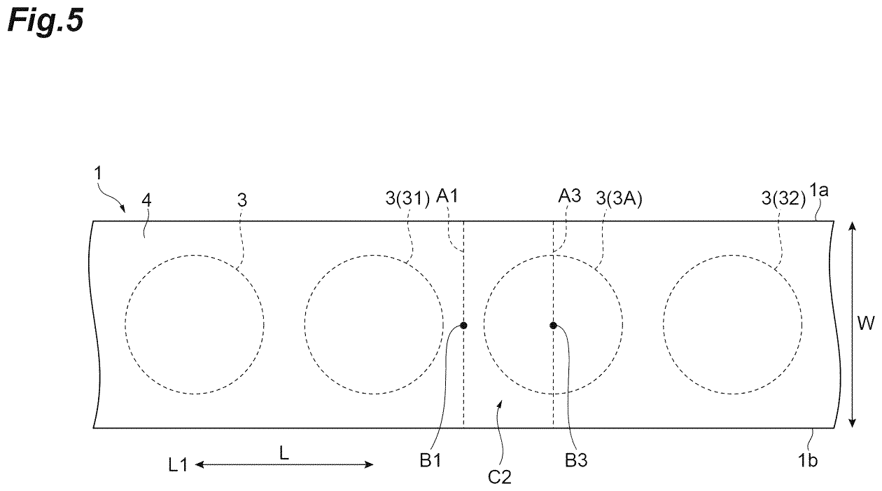

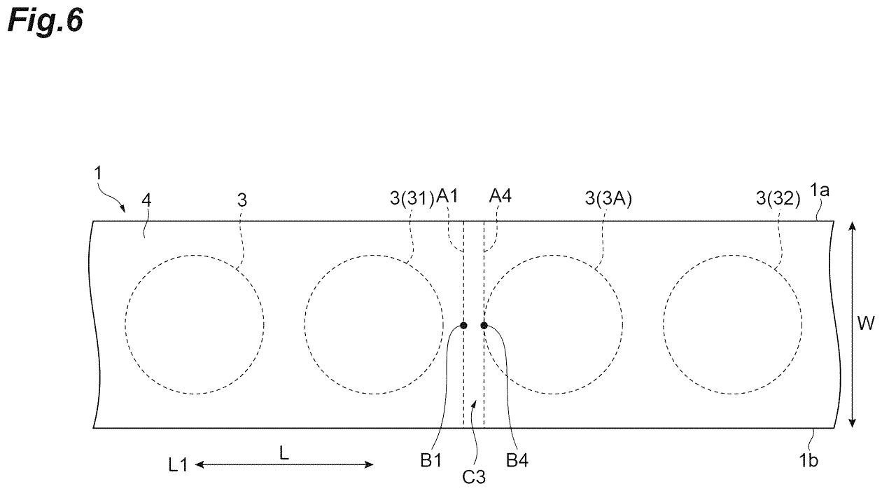

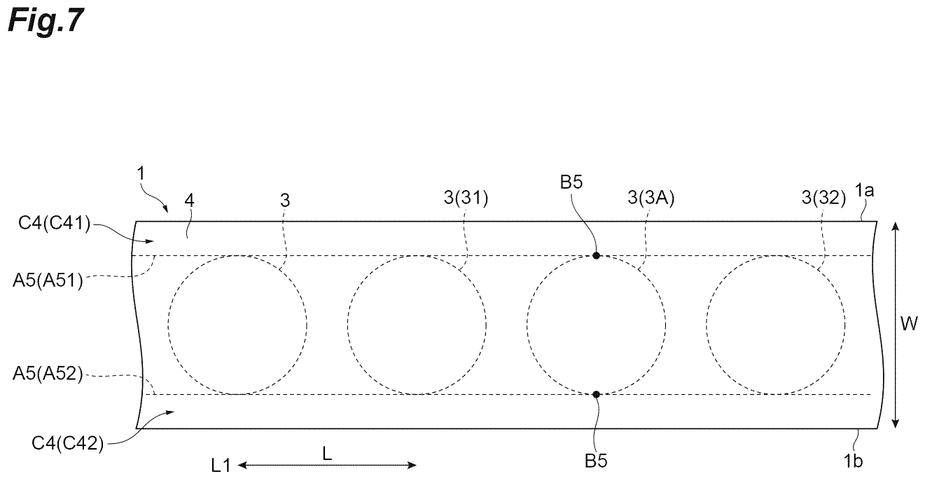

FIGS. 4 to 7 are plan views illustrating an example of a region in which a defective-product identifying marking is provided. As illustrated in FIGS. 1 and 4 to 7, a pair of adhesive layers 3 adjacent to the defective adhesive layer 3A in the longitudinal direction L among the plurality of adhesive layers 3 are defined as a first adhesive layer 31 and a second adhesive layer 32. The first adhesive layer 31 is an adhesive layer 3 adjacent to the defective adhesive layer 3A on a side of the first longitudinal direction L1, and the second adhesive layer 32 is an adhesive layer 3 adjacent to the defective adhesive layer 3A on a side opposite to the first longitudinal direction L1. A virtual line that passes through a middle B1 between the first adhesive layer 31 and the defective adhesive layer 3A and extends in the width direction W is defined as a first virtual line A1 (see FIGS. 4 to 6). A virtual line that passes through a middle B2 between the second adhesive layer 32 and the defective adhesive layer 3A and extends in the width direction W is defined as a second virtual line A2 (see FIG. 4). A virtual line that passes through a middle B3 of the defective adhesive layer 3A and extends in the width direction W is defined as a third virtual line A3 (see FIG. 5). A virtual line that passes through an end B4 on a side of the first adhesive layer 31 of the defective adhesive layer 3A and extends in the width direction W is defined as a fourth virtual line A4 (see FIGS. 1 and 6). A pair of virtual lines that pass through both ends B5 and B5 of the defective adhesive layer 3A in the width direction W and extend in the longitudinal direction L are defined as fifth virtual lines A5 and A5 (see FIG. 7).

The defective-product identifying marking 5 may be provided, for example, in a first region C1, which is a region from the first virtual line A1 to the second virtual line A2 on the pressure-sensitive adhesive film 4, as illustrated in FIG. 4. In addition, the defective-product identifying marking 5 may be provided, for example, in a second region C2, which is a region from the first virtual line A1 to the third virtual line A3 on the pressure-sensitive adhesive film 4, as illustrated in FIG. 5. In addition, the defective-product identifying marking 5 may be provided, for example, in a third region C3, which is a region from the first virtual line A1 to the fourth virtual line A4 on the pressure-sensitive adhesive film 4, as illustrated in FIG. 6. In addition, the defective-product identifying marking 5 may be provided, for example, in fourth regions C4 and C4, which are regions on a side opposite to the defective adhesive layer 3A with respect to the pair of fifth virtual lines A5 and A5, as illustrated in FIG. 7. Of the fourth regions C4 and C4, the fourth region C4 located at one end 1a is defined as a fourth region C41, and the fourth region C4 located at the other end 1b is defined as a fourth region C42. In addition, of the pair of fifth virtual lines A5 and A5, the fifth virtual line A5 located at one end 1a is defined as a fifth virtual line A51, and the fifth virtual line A5 located at the other end 1b is defined as a fifth virtual line A52. In this case, the fourth region C41 is a region at one end 1a of the fifth virtual line A51, and the fourth region C42 is a region at the other end 1b of the fifth virtual line A52.

The defective-product identifying marking 5 may be provided on the plurality of adhesive layers 3 of the pressure-sensitive adhesive film 4, but is preferably provided on a non-adhesive-layer region D (see FIG. 1) excluding the plurality of adhesive layers 3 of the pressure-sensitive adhesive film 4.

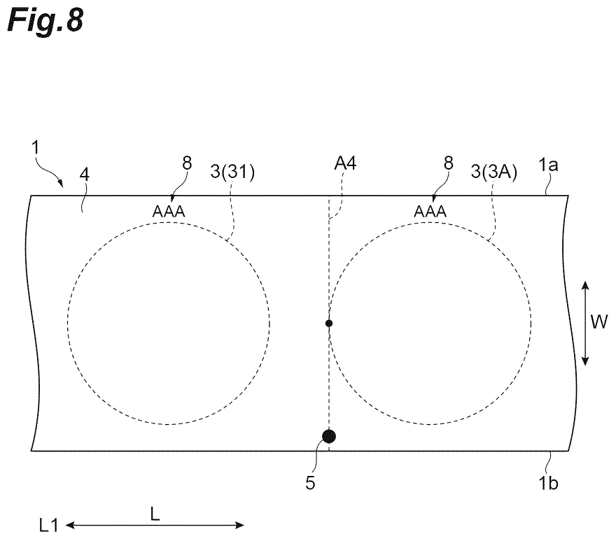

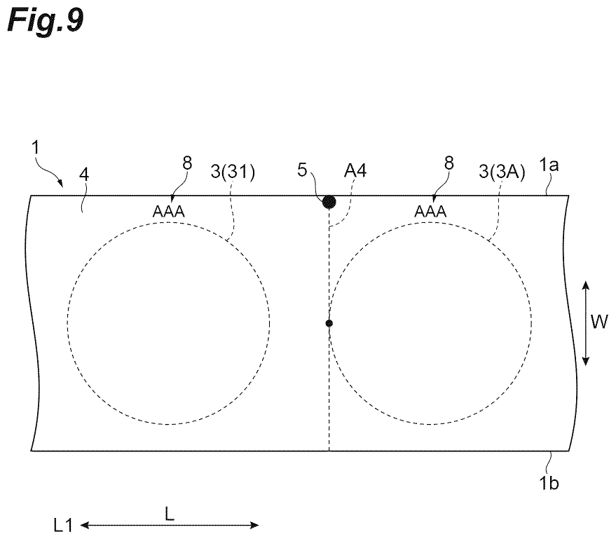

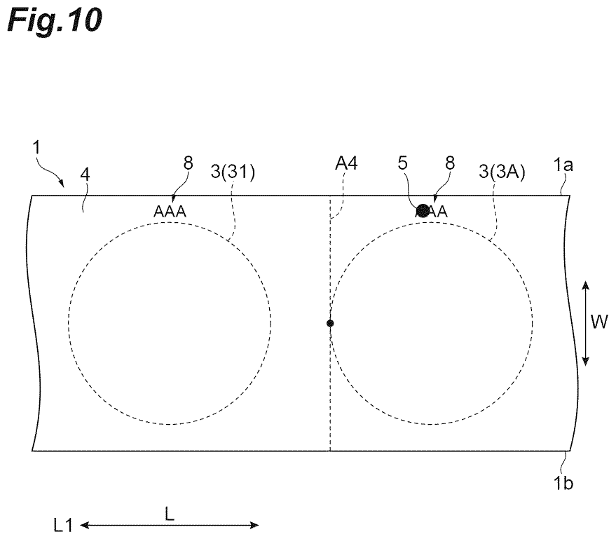

FIGS. 8 to 11 are plan views illustrating an example of a position of the defective-product identifying marking. The defective-product identifying marking 5 may be provided, for example, on the fourth virtual line A4, as illustrated in FIG. 1. In addition, the defective-product identifying marking 5 may also be provided, for example, at an end portion on a side of one end 1a in the width direction W spaced apart from one end 1a, that is, in the vicinity of one end 1a, as illustrated in FIG. 1. In addition, the defective-product identifying marking 5 may also be provided, for example, at an end portion on a side of the other end 1b in the width direction W spaced apart from the other end 1b, that is, in the vicinity of the other end 1b, as illustrated in FIG. 8. In addition, the defective-product identifying marking 5 may also be provided, for example, at an end on a side of the other end 1b in the width direction W, as illustrated in FIG. 9. In addition, the defective-product identifying marking 5 may be provided, for example, at a position spaced apart from the fourth virtual line A4, as illustrated in FIG. 10. In addition, the defective-product identifying marking 5 may be provided, for example, on the identification character information 8, as illustrated in FIG. 10.

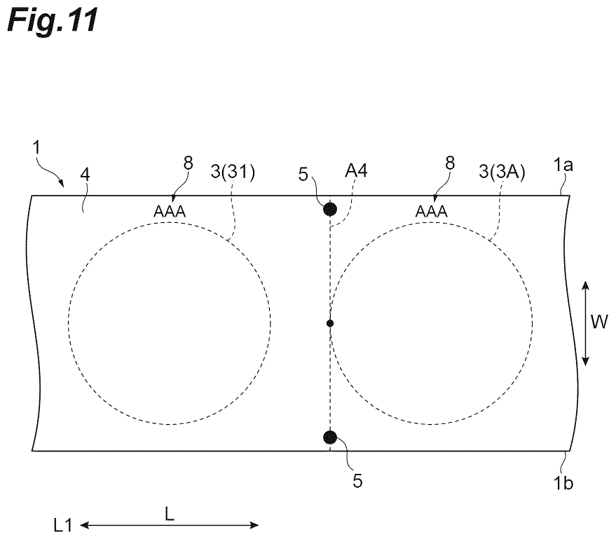

When a plurality of defective-product identifying markings 5 are provided for one defective adhesive layer 3A, the plurality of defective-product identifying markings 5 are provided at different positions from each other. For example, as illustrated in FIG. 11, when two defective-product identifying markings 5 are provided for one defective adhesive layer 3A, one of the defective-product identifying markings 5 may be provided in the vicinity of one end 1a, and the other defective-product identifying marking 5 may be provided in the vicinity of the other end 1b.

The defective-product identifying marking 5 may have any shape. The defective-product identifying marking 5 may be a linear symbol or a drawing, may be a filled figure, or may be a code symbol.

Examples of the linear symbol include an alphabet letter, a Greek letter, a numeral, an X mark, a horizontal line, a vertical line, a single diagonal line, a multiple diagonal line, a check mark, a circle mark, a star mark, a spiral mark, a single wavy line, a multiple wavy line, a >mark, a <mark, a ≥mark, a ≤mark, an asterisk, and a dot.

Examples of the figure of the defective-product identifying marking 5 include a circular shape, a polygonal shape, a star shape, a Torx (registered trademark) shape, a serrated circular shape, a crescent shape, a semicircular shape, a flower shape, a Y shape, an X shape, an M shape, a V shape, a U shape, a shape having a convex portion, and a shape having a concave portion. The circular shape includes, for example, a perfect circular shape, an elliptical shape, and the like. The polygonal shape includes a triangle, a quadrilateral, a pentagon, a hexagon, and the like. The quadrilateral includes a square, a rectangle, a trapezoid, a rhombus, and the like. The triangle includes an equilateral triangle, an isosceles triangle, a right triangle, an inverted triangle, and the like.

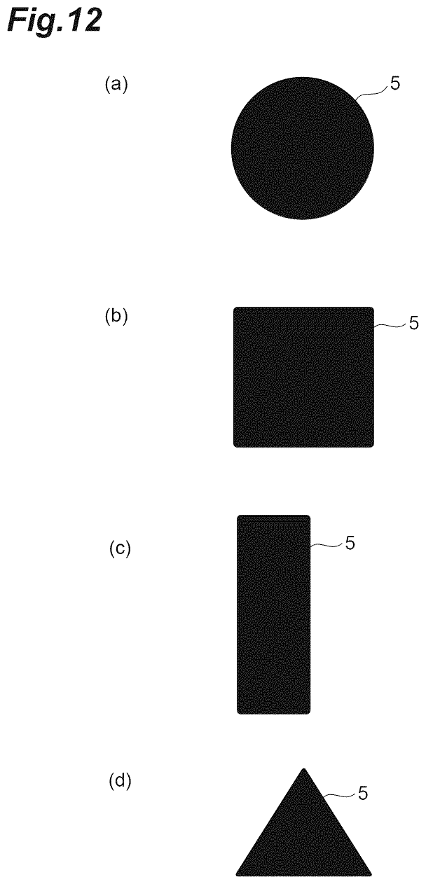

FIG. 12(a), 12(b), 12(c), and 12(d) are plan views of defective-product identifying markings for explaining examples of shapes of defective-product identifying markings. FIG. 12(a) illustrates an example of a circular defective-product identifying marking 5. FIG. 12(b) to 12(d) illustrate examples of polygonal defective-product identifying markings 5. FIG. 12(b) illustrates an example of a square defective-product identifying marking 5. FIG. 12(c) illustrates an example of a rectangular defective-product identifying marking 5, and FIG. 12(d) illustrates an example of a triangular defective-product identifying marking 5.

The filled figure refers not to a figure consisting only of an outline but to a figure in which the inside of the outline is filled. The defective-product identifying markings 5 illustrated in FIG. 12(a), 12(b), 12(c), and 12(d) illustrate examples of filled figures.

The code symbol is a symbol to which various kinds of information are associated. Examples of the code symbol include a one-dimensional barcode and a two-dimensional barcode. Examples of the one-dimensional barcode include Interleaved 2 of 5 (ITF), which consists only of numerals, and Code 39, which includes numerals, alphabet letters, and symbols. Examples of the two-dimensional barcode include a stacked two-dimensional barcode and a matrix-type two-dimensional code such as a QR Code (registered trademark).

The defective-product identifying marking 5 may be printed on the pressure-sensitive adhesive film 4, may be a seal attached to the pressure-sensitive adhesive film 4, may be a slit (notch) formed in the laminated film 1, or may be a hole formed in the laminated film 1.

When the defective-product identifying marking 5 is a seal attached to the pressure-sensitive adhesive film 4, a thickness of the seal is, for example, 20 μm to 200 μm.

The slit (notch) serving as the defective-product identifying marking 5 is a notch extending from one end 1a or the other end 1b of the laminated film 1. That is, the slit (notch) is a notch opened to one end 1a or the other end 1b of the laminated film 1. When the defective-product identifying marking 5 is a slit formed in the laminated film 1, examples of the shape of the slit serving as the defective-product identifying marking 5 include a circular shape, a polygonal shape, a star shape, a Torx (registered trademark) shape, a serrated circular shape, a crescent shape, a semicircular shape, a flower shape, an M shape, a V shape, a U shape, a shape having a convex portion, and a shape having a concave portion. The circular shape includes, for example, a perfect circular shape, an elliptical shape, and the like. The polygonal shape includes a triangle, a quadrilateral, a pentagon, a hexagon, and the like. The quadrilateral includes a square, a rectangle, a trapezoid, a rhombus, and the like. The triangle includes an equilateral triangle, an isosceles triangle, a right triangle, an inverted triangle, and the like.

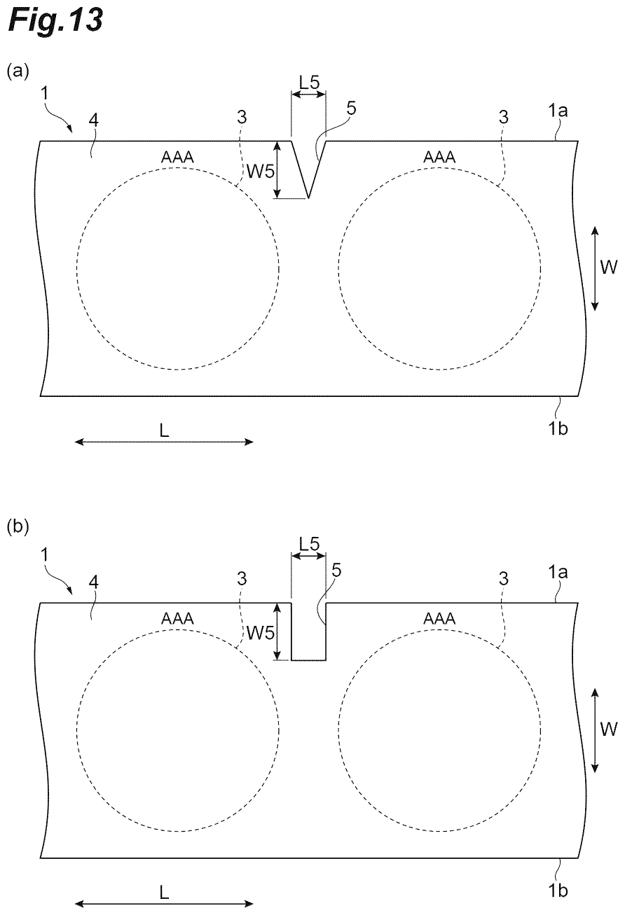

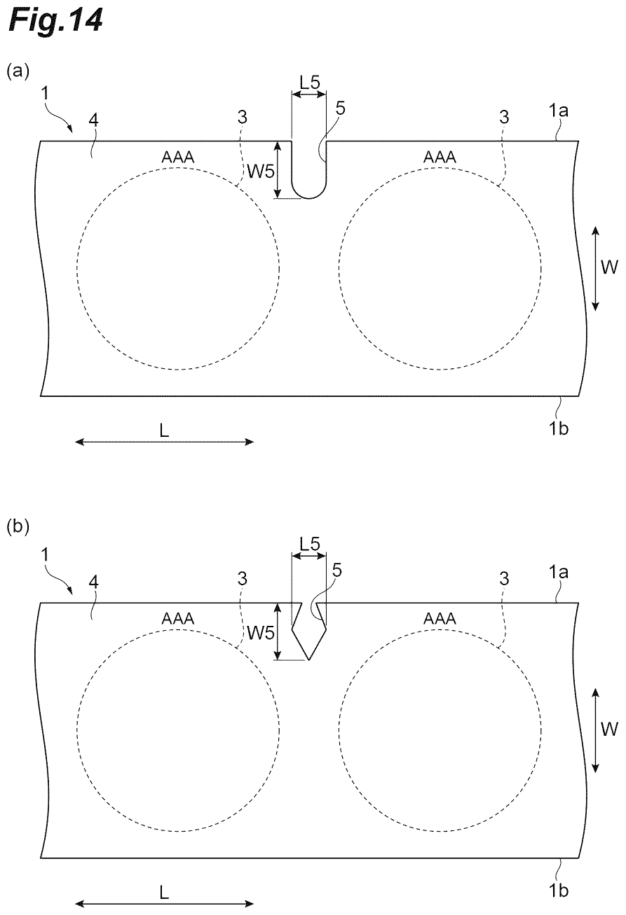

FIG. 13(a), 13(b), 14(a), and 14(b) are plan views of laminated films for explaining examples of shapes of slits serving as defective-product identifying markings. FIG. 13(a) illustrates an example of a triangular slit serving as the defective-product identifying marking 5. FIG. 13(b) illustrates an example of a quadrilateral slit serving as the defective-product identifying marking 5. FIG. 14(a) illustrates an example of a U-shaped slit serving as the defective-product identifying marking 5. FIG. 14(b) illustrates an example of a pentagonal slit serving as the defective-product identifying marking 5.

When the defective-product identifying marking 5 is a slit formed in the laminated film 1, the end of the defective-product identifying marking 5 in the longitudinal direction L may be formed in a curved shape. The defective-product identifying marking 5 illustrated in FIG. 14(a) shows an example of a slit of the defective-product identifying marking 5 in which the end in the longitudinal direction L is formed in a curved shape.

When the defective-product identifying marking 5 is a slit formed in the laminated film 1, a length LS of the slit in the longitudinal direction L may be 10 mm or more and 100 mm or less, preferably 15 mm or more and 80 mm or less, and more preferably 20 mm or more and 50 mm or less. When the length of the slit in the longitudinal direction L is not constant, the length L5 of the slit in the longitudinal direction L is defined as a maximum length of the slit in the longitudinal direction L.

When the defective-product identifying marking 5 is a slit formed in the laminated film 1, a width W5 of the slit in the width direction W may be 2 mm or more and 40 mm or less, preferably 5 mm or more and 30 mm or less, and more preferably 10 mm or more and 20 mm or less. When the width of the slit in the width direction W is not constant, the width W5 of the slit in the width direction W is defined as a maximum width of the slit in the width direction W.

When the defective-product identifying marking 5 is a hole formed in the laminated film 1, examples of the shape of the hole serving as the defective-product identifying marking 5 include a circular shape, a polygonal shape, a star shape, a Torx (registered trademark) shape, a serrated circular shape, a crescent shape, a semicircular shape, a flower shape, an M shape, a V shape, a U shape, a shape having a convex portion, and a shape having a concave portion. The circular shape includes, for example, a perfect circular shape, an elliptical shape, and the like. The polygonal shape includes a triangle, a quadrilateral, a pentagon, a hexagon, and the like. The quadrilateral includes a square, a rectangle, a trapezoid, a rhombus, and the like. The triangle includes an equilateral triangle, an isosceles triangle, a right triangle, an inverted triangle, and the like.

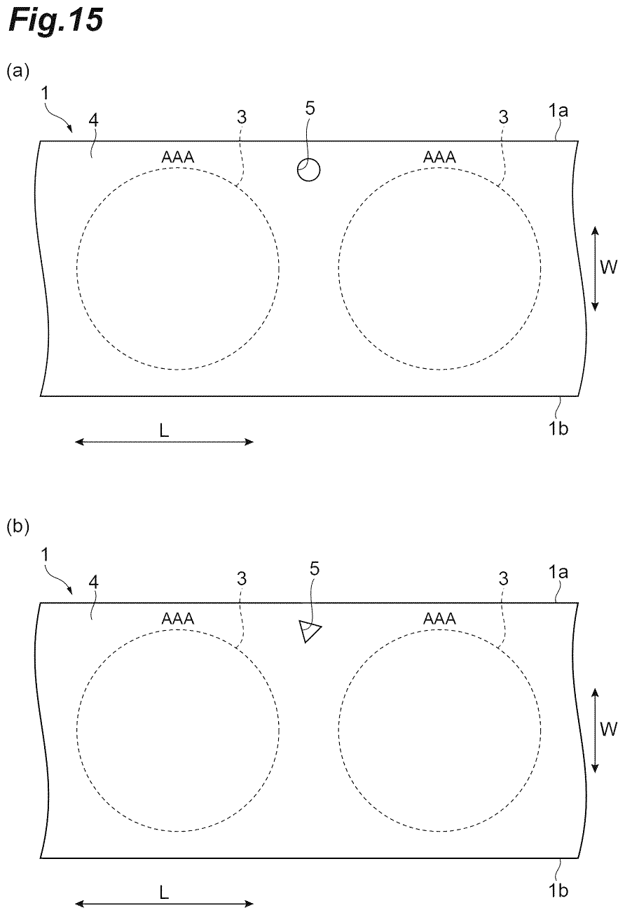

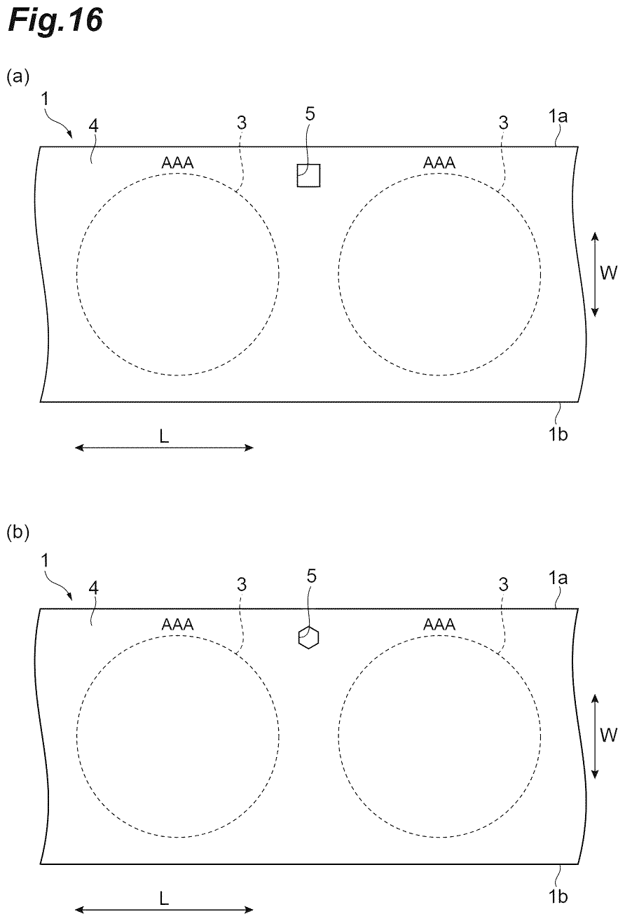

FIG. 15(a), 15(b), 16(a), and 16(b) are plan views of laminated films for explaining examples of shapes of holes serving as defective-product identifying markings. FIG. 15(a) illustrates an example of a circular hole serving as the defective-product identifying marking 5. FIG. 15(b) illustrates an example of a triangular hole serving as the defective-product identifying marking 5. FIG. 16(a) illustrates an example of a quadrilateral hole serving as the defective-product identifying marking 5. FIG. 16(b) illustrates an example of a hexagonal slit serving as the defective-product identifying marking 5.

An area of the defective-product identifying marking 5 is, for example, 50 mm² or more and 1500 mm² or less, 300 mm² or more and 1300 mm² or less, or 600 mm² or more and 1000 mm² or less. When a non-filled portion exists in the defective-product identifying marking 5, an area of the defective-product identifying marking 5 is defined as an area of a filled portion.

A total light transmittance of the defective-product identifying marking 5 may be clearly different from a total light transmittance of the dicing/die bonding integrated film, and is, for example, 0% or more and 10% or less, 0% or more and 8% or less, or 0% or more and 5% or less. The total light transmittance of the defective-product identifying marking 5 is a total light transmittance of the entire defective-product identifying markings 5. Therefore, when a non-filled portion exists in the defective-product identifying marking 5, the total light transmittance of the defective-product identifying marking 5 is defined as a total light transmittance of the entire defective-product identifying markings 5 including the non-filled portion.

### Method for Producing Laminated Film

Subsequently, a method for producing the laminated film 1 described above will be described. The method for producing a laminated film according to the present embodiment includes a preparation step, an inspection step, and a marking step.

In the preparation step, a raw film 101 (see FIG. 17) including an elongated protective film 2, a plurality of adhesive layers 3 provided on the protective film 2, and a pressure-sensitive adhesive film 4 provided on the protective film 2 and the plurality of adhesive layers 3 so as to cover the plurality of adhesive layers 3 is prepared. The raw film 101 is a film in which the defective-product identifying marking 5 is not provided in the laminated film 1. In the preparation step, as the raw film 101, a roll in which the raw film 101 is wound into a roll is prepared.

In the inspection step, the plurality of adhesive layers 3 of the raw film 101 are inspected while unwinding the raw film 101 from a roll in which the raw film 101 is wound into a roll. In the inspection step, it is determined whether adhesive layer 3 is a non-defective product or a defective product.

In the marking step, the defective-product identifying marking 5 is provided on the pressure-sensitive adhesive film 4 at a position corresponding to a defective adhesive layer 3A, which is an adhesive layer 3 determined to be a defective product in the inspection step. On the other hand, no defective-product identifying marking 5 is provided at a position corresponding to an adhesive layer 3 determined to be a non-defective product in the inspection step. As a result, a laminated film 1 in which the defective-product identifying marking 5 is provided on the pressure-sensitive adhesive film 4 at a position corresponding to the defective adhesive layer 3A is produced.

Each of the above steps is performed using, for example, the inspection apparatus 10 illustrated in FIG. 17. FIG. 17 is a schematic view illustrating a configuration of an inspection apparatus applied to a method for producing a laminated film according to an embodiment. The inspection apparatus 10 illustrated in FIG. 17 includes a plurality of conveying rollers 11, an inspection unit 12, and a mark applying unit 13.

The conveying roller 11 conveys the raw film 101 (laminated film 1) between a feeding roller (not illustrated) and a winding roller (not illustrated). A predetermined tension is applied to the raw film 101 (laminated film 1) being conveyed by the plurality of conveying rollers 11.

The inspection unit 12 includes, for example, a light emitting portion that outputs detection light, and a light receiving portion to which the detection light transmitted through or reflected from the raw film 101 is input. The inspection unit 12 inspects the plurality of adhesive layers 3 of the raw film 101 by identifying an abnormality when the received light amount exceeds or falls below a set value.

The mark applying unit 13 includes, for example, a base portion, and a pressing portion that is disposed on the opposite side of the attaching portion with respect to the conveyance path of the raw film 101 and presses a seal-like defective-product identifying marking 5 against the pressure-sensitive adhesive film 4 of the raw film 101. The mark applying unit 13 presses the defective-product identifying marking 5 onto the pressure-sensitive adhesive film 4 at a position corresponding to a defective adhesive layer 3A, which is an adhesive layer 3 determined to be a defective product by the inspection unit 12. On the other hand, the mark applying unit 13 does not press the defective-product identifying marking 5 against a position corresponding to an adhesive layer 3 determined to be a non-defective product by the inspection unit 12. As a result, the defective-product identifying marking 5 is attached onto the pressure-sensitive adhesive film 4 at a position corresponding to the defective adhesive layer 3A. Note that the position corresponding to the defective adhesive layer 3A on the pressure-sensitive adhesive film 4 can be specified, for example, based on the conveyance distance of the raw film 101 from the inspection position of the inspection unit 12 to the attaching position of the mark applying unit 13, and the conveyance speed of the raw film 101.

As described above, in the laminated film 1 according to the present embodiment, since the defective-product identifying marking 5 is provided on the pressure-sensitive adhesive film 4 at a position corresponding to a defective adhesive layer 3A, the position of the defective adhesive layer 3A can be specified by detecting the defective-product identifying marking 5 when manufacturing a semiconductor device. Therefore, by attaching the adhesive layers 3 excluding the defective adhesive layer 3A to a semiconductor wafer, the occurrence of a defective semiconductor device can be suppressed.

In addition, in the laminated film 1, since the pressure-sensitive adhesive film 4 is provided on the protective film 2 and the plurality of adhesive layers 3 so as to cover the plurality of adhesive layers 3, and the defective-product identifying marking 5 is provided on the pressure-sensitive adhesive film 4, the defective-product identifying marking 5 can be detected even after the adhesive layers 3 are peeled from the protective film 2.

In addition, in the laminated film 1, since the plurality of adhesive layers 3 are arranged in the longitudinal direction L so as to be spaced apart from each other, the adhesive layers 3 can be easily attached to a semiconductor wafer.

In addition, in the laminated film 1, when the defective-product identifying marking 5 is provided in the first region C1 from the first virtual line A1 that passes through the middle B1 between the first adhesive layer 31 and the defective adhesive layer 3A and extends in the width direction W to the second virtual line A2 that passes through the middle B2 between the second adhesive layer 32 and the defective adhesive layer 3A and extends in the width direction W, the position of the defective adhesive layer 3A can be easily specified from the defective-product identifying marking 5.

In addition, in the laminated film 1, when the defective-product identifying marking 5 is provided in the second region C2 from the first virtual line A1 that passes through the middle B1 between the first adhesive layer 31 and the defective adhesive layer 3A and extends in the width direction W to the third virtual line A3 that passes through the middle B3 of the defective adhesive layer 3A and extends in the width direction W, the position of the defective adhesive layer 3A can be easily specified from the defective-product identifying marking 5. In particular, when the laminated film 1 is conveyed from the first longitudinal direction L1 and the adhesive layer 3 and the defective-product identifying marking 5 are detected, a deviation between a detection timing of the adhesive layer 3 and a detection timing of the defective-product identifying marking 5 can be reduced, such that a position of the defective adhesive layer 3A can be identified more easily from the defective-product identifying marking 5.

In addition, in the laminated film 1, when the defective-product identifying marking 5 is provided in the third region C3 from the first virtual line A1 that passes through the middle B1 between the first adhesive layer 31 and the defective adhesive layer 3A and extends in the width direction W to the fourth virtual line A4 that passes through the end B4 on a side of the first adhesive layer 31 of the defective adhesive layer 3A and extends in the width direction W, the position of the defective adhesive layer 3A can be easily specified from the defective-product identifying marking 5. In particular, when the laminated film 1 is conveyed from the first longitudinal direction L1 and the adhesive layer 3 and the defective-product identifying marking 5 are detected, a deviation between a detection timing of the adhesive layer 3 and a detection timing of the defective-product identifying marking 5 can be reduced, such that a position of the defective adhesive layer 3A can be identified more easily from the defective-product identifying marking 5.

In addition, in the laminated film 1, in a case where the defective-product identifying marking 5 is provided in fourth regions C4 and C4 on a side opposite to the defective adhesive layer 3A with respect to a pair of fifth virtual lines A5 and A5 that pass through both ends B5 and B5 of the defective adhesive layer 3A in the width direction W and extend in the longitudinal direction L, even when the defective-product identifying marking 5 has a thickness, it is possible to suppress the shape of the defective-product identifying marking 5 from being transferred to the adhesive layer 3.

In addition, in the laminated film 1, when the defective-product identifying marking 5 is provided on the non-adhesive-layer region D, it is possible to reduce an influence on the adhesive layers caused by providing the defective-product identifying marking.

When the defective-product identifying marking is a linear character such as an alphabet or a numeral, it is difficult to detect the defective-product identifying marking 5. In the laminated film 1, since the defective-product identifying marking 5 is a filled figure, the defective-product identifying marking 5 can be easily detected. Moreover, even when identification character information 8 for identifying the adhesive layer 3 is provided on the laminated film 1, the identification character information 8 and the defective-product identifying marking 5 can be easily distinguished from each other.

In addition, in the laminated film 1, when the area of the defective-product identifying marking 5 is 50 mm² or more and 1500 mm² or less, 300 mm² or more and 1300 mm² or less, or 600 mm² or more and 1000 mm² or less, the defective-product identifying marking 5 can be easily detected.

In addition, in the laminated film 1, when the total light transmittance of the defective-product identifying marking 5 is 0% or more and 10% or less, 0% or more and 8% or less, or 0% or more and 5% or less, the defective-product identifying marking 5 can be easily detected.

In addition, in the laminated film 1, in a case where the defective-product identifying marking 5 is a code symbol, by associating information relating to the defective adhesive layer 3A with the code symbol, the information relating to the defective adhesive layer 3A can be obtained when the defective-product identifying marking 5 is detected.

In addition, in the laminated film 1, when the defective-product identifying marking 5 is an X mark, the defective-product identifying marking 5 can be easily detected visually.

In addition, in the laminated film 1, when the defective-product identifying marking 5 is a slit formed in the laminated film 1, the defective-product identifying marking 5 can be easily detected.

In addition, in the laminated film 1, in a case where the end of the defective-product identifying marking 5 in the longitudinal direction L is formed in a curved shape, it is possible to suppress concentration of stress at the end of the defective-product identifying marking 5 in the longitudinal direction L when the laminated film is pulled in the longitudinal direction L. Accordingly, it is possible to suppress the laminated film 1 from being broken starting from the end of the defective-product identifying marking 5 in the longitudinal direction L.

In addition, in the laminated film 1, when the length L5 of the slit in the longitudinal direction L is 10 mm or more and 100 mm or less, preferably 15 mm or more and 80 mm or less, and more preferably 20 mm or more and 50 mm or less, the defective-product identifying marking can be easily detected, and it is also possible to suppress breakage when the laminated film is pulled in the longitudinal direction L.

In addition, in the laminated film 1, when the width W5 of the slit in the width direction W is 2 mm or more and 40 mm or less, preferably 5 mm or more and 30 mm or less, and more preferably 10 mm or more and 20 mm or less, the defective-product identifying marking 5 can be easily detected, and it is also possible to suppress breakage when the laminated film is pulled in the longitudinal direction L.

In addition, in the laminated film 1, when the defective-product identifying marking 5 is a hole formed in the laminated film 1, it is possible to easily detect the defective-product identifying marking 5 while suppressing breakage when the laminated film is pulled in the longitudinal direction L.

In addition, in the laminated film 1, when one defective-product identifying marking 5 is provided for one defective adhesive layer 3A, it is possible to minimize the number of defective-product identifying markings 5 and suppress contamination of the adhesive layers 3 caused by the defective-product identifying markings 5.

In addition, in the laminated film 1, when a plurality of defective-product identifying markings 5 are provided at different positions for one defective adhesive layer 3A, a degree of freedom in placing a mark detection unit for detecting the defective-product identifying markings 5 can be increased. Moreover, when semiconductor devices are manufactured in a plurality of facilities having different installation positions of mark detection units for detecting the defective-product identifying markings 5, versatility of the laminated film 1 can be enhanced by providing the defective-product identifying markings 5 at positions corresponding to the respective facilities.

In the method for producing a laminated film according to the present embodiment, since the plurality of adhesive layers 3 of the raw film 101 are inspected and a defective-product identifying marking 5 is provided on the pressure-sensitive adhesive film 4 at a position corresponding to a defective adhesive layer 3A, it is possible to produce a laminated film 1 capable of suppressing occurrence of defective semiconductor devices.

In the step of using the laminated film according to the present embodiment, by peeling the plurality of adhesive layers 3 and the pressure-sensitive adhesive film 4 from the protective film 2 and detecting the defective-product identifying marking 5, the adhesive layers 3 other than the defective adhesive layer 3A provided at a position corresponding to the defective-product identifying marking 5 can be attached to a semiconductor wafer. As a result, the occurrence of a defective semiconductor device can be suppressed.

Although the laminated film, the method for producing a laminated film, and the method for manufacturing a semiconductor device according to an embodiment of the present disclosure have been described, the present disclosure is not limited to the embodiment described above and can be appropriately changed without departing from the spirit of the present disclosure.

For example, in the above embodiment, the pressure-sensitive adhesive film 4 has been described as being provided on the protective film 2 and the plurality of adhesive layers 3 so as to cover the entire one surface 2a of the protective film 2 and the plurality of adhesive layers 3. However, the pressure-sensitive adhesive film 4 may not cover the entire one surface 2a of the protective film 2, and may be provided only on the plurality of adhesive layers 3. In this case, the defective-product identifying marking 5 may be provided on the protective film 2 instead of on the pressure-sensitive adhesive film 4.

The gist of the present disclosure is as follows [1] to [21].

[1] A laminated film including: an elongated protective film; a plurality of adhesive layers provided on the protective film; a pressure-sensitive adhesive film provided on the plurality of adhesive layers; and a defective-product identifying marking provided on the pressure-sensitive adhesive film at a position corresponding to a defective adhesive layer being an adhesive layer determined to be a defective product among the plurality of adhesive layers.

[2] The laminated film according to [1], in which the pressure-sensitive adhesive film is provided on the protective film and the plurality of adhesive layers so as to cover the plurality of adhesive layers, and the defective-product identifying marking is provided on the pressure-sensitive adhesive film.

[3] The laminated film according to [1] or [2], in which the plurality of adhesive layers are arranged in a longitudinal direction of the protective film so as to be spaced apart from each other.

[4] The laminated film according to [3], in which when a pair of adhesive layers adjacent to the defective adhesive layer in the longitudinal direction among the plurality of adhesive layers are defined as a first adhesive layer and a second adhesive layer, the defective-product identifying marking is provided in a region from a first virtual line that passes through a middle between the first adhesive layer and the defective adhesive layer and extends in a width direction orthogonal to the longitudinal direction of the protective film to a second virtual line that passes through a middle between the second adhesive layer and the defective adhesive layer and extends in the width direction.

[5] The laminated film according to [4], in which the defective-product identifying marking is provided in a region from the first virtual line to a third virtual line that passes through a middle of the defective adhesive layer and extends in the width direction.

[6] The laminated film according to [4] or [5], in which the defective-product identifying marking is provided in a region from the first virtual line to a fourth virtual line that passes through an end on a side of the first adhesive layer of the defective adhesive layer and extends in the width direction.

[7] The laminated film according to any one of [3] to [6], in which the defective-product identifying marking is provided in regions on a side opposite to the defective adhesive layer with respect to a pair of fifth virtual lines that pass through both ends of the defective adhesive layer in a width direction of the protective film orthogonal to the longitudinal direction and extend in the longitudinal direction.

[8] The laminated film according to any one of [1] to [7], in which the defective-product identifying marking is provided on a non-adhesive-layer region of the pressure-sensitive adhesive film excluding the plurality of adhesive layers.

[9] The laminated film according to any one of [1] to [8], in which the defective-product identifying marking is a filled figure.

[10] The laminated film according to any one of [1] to [9], in which an area of the defective-product identifying marking is 50 mm² or more and 1500 mm² or less.

[11] The laminated film according to any one of [1] to [10], in which a total light transmittance of the defective-product identifying marking is 0% or more and 10% or less.

[12] The laminated film according to any one of [1] to [11], in which the defective-product identifying marking is a code symbol.

[13] The laminated film according to any one of [1] to [11], in which the defective-product identifying marking is an X mark.

[14] The laminated film according to any one of [1] to [11], in which the defective-product identifying marking is a slit formed in the laminated film.

[15] The laminated film according to [14], in which an end of the defective-product identifying marking in a longitudinal direction of the protective film is formed in a curved shape.

[16] The laminated film according to [14] or [15], in which a length of the slit in a longitudinal direction of the protective film is 10 mm or more and 100 mm or less.

[17] The laminated film according to any one of [14] to [16], in which a width of the slit in a width direction orthogonal to a longitudinal direction of the protective film is 2 mm or more and 40 mm or less.

[18] The laminated film according to any one of [1] to [11], in which the defective-product identifying marking is a hole formed in the laminated film.

[19] The laminated film according to any one of [1] to [18], in which one defective-product identifying marking is provided for one defective adhesive layer.

[20] The laminated film according to any one of [1] to [18], in which a plurality of defective-product identifying markings are provided at different positions for one defective adhesive layer.

[21] A method for producing a laminated film for producing the laminated film according to any one of [1] to [20], the method including: a preparation step of preparing a raw film including an elongated protective film, a plurality of adhesive layers provided on the protective film, and a pressure-sensitive adhesive film provided on the plurality of adhesive layers; an inspection step of inspecting the plurality of adhesive layers of the raw film; and a marking step of providing a defective-product identifying marking on the pressure-sensitive adhesive film at a position corresponding to a defective adhesive layer being the adhesive layer determined to be a defective product in the inspection step.

### REFERENCE SIGNS LIST

1 Laminated film
1a One end
1b Other end
2 Protective film
2a One surface
3 Adhesive layer
3A Defective adhesive layer
4 Pressure-sensitive adhesive film
5 Defective-product identifying marking
6 Pressure-sensitive adhesive layer
7 Base material film
8 Identification character information
9 Roll
10 Inspection apparatus
11 Conveying roller
12 Inspection unit
13 Mark applying unit
31 First adhesive layer
32 Second adhesive layer
101 Raw film
A1 First virtual line
A2 Second virtual line
A3 Third virtual line
A4 Fourth virtual line
A5 Fifth virtual line
A51 Fifth virtual line
A52 Fifth virtual line
B1 Middle
B2 Middle
B3 Middle
B4 End
B5 Both ends
C1 First region
C2 Second region
C3 Third region
C4 Fourth region
C41 Fourth region
C42 Fourth region
D Non-adhesive-layer region
L Longitudinal direction
L1 First longitudinal direction
L5 Length
W Width direction
W5 Width

1. A laminated film comprising:
an elongated protective film;
a plurality of adhesive layers provided on the protective film;
a pressure-sensitive adhesive film provided on the plurality of adhesive layers; and
a defective-product identifying marking provided on the pressure-sensitive adhesive film at a position corresponding to a defective adhesive layer being an adhesive layer determined to be a defective product among the plurality of adhesive layers.

2. The laminated film according to claim 1, wherein the pressure-sensitive adhesive film is provided on the protective film and the plurality of adhesive layers so as to cover the plurality of adhesive layers, and
the defective-product identifying marking is provided on the pressure-sensitive adhesive film.

3. The laminated film according to claim 1, wherein the plurality of adhesive layers are arranged in a longitudinal direction of the protective film so as to be spaced apart from each other.

4. The laminated film according to claim 3, wherein when a pair of adhesive layers adjacent to the defective adhesive layer in the longitudinal direction among the plurality of adhesive layers are defined as a first adhesive layer and a second adhesive layer,
the defective-product identifying marking is provided in a region from a first virtual line that passes through a middle between the first adhesive layer and the defective adhesive layer and extends in a width direction orthogonal to the longitudinal direction of the protective film to a second virtual line that passes through a middle between the second adhesive layer and the defective adhesive layer and extends in the width direction.

5. The laminated film according to claim 4, wherein the defective-product identifying marking is provided in a region from the first virtual line to a third virtual line that passes through a middle of the defective adhesive layer and extends in the width direction.

6. The laminated film according to claim 4, wherein the defective-product identifying marking is provided in a region from the first virtual line to a fourth virtual line that passes through an end on a side of the first adhesive layer of the defective adhesive layer and extends in the width direction.

7. The laminated film according to claim 3, wherein the defective-product identifying marking is provided in regions on a side opposite to the defective adhesive layer with respect to a pair of fifth virtual lines that pass through both ends of the defective adhesive layer in a width direction of the protective film orthogonal to the longitudinal direction and extend in the longitudinal direction.

8. The laminated film according to claim 1, wherein the defective-product identifying marking is provided on a non-adhesive-layer region of the pressure-sensitive adhesive film excluding the plurality of adhesive layers.

9. The laminated film according to claim 1, wherein the defective-product identifying marking is a filled figure.

10. The laminated film according to claim 1, wherein an area of the defective-product identifying marking is 50 mm² or more and 1500 mm² or less.

11. The laminated film according to claim 1, wherein a total light transmittance of the defective-product identifying marking is 0% or more and 10% or less.

12. The laminated film according to claim 1, wherein the defective-product identifying marking is a code symbol.

13. The laminated film according to claim 1, wherein the defective-product identifying marking is an X mark.

14. The laminated film according to claim 1, wherein the defective-product identifying marking is a slit formed in the laminated film.

15. The laminated film according to claim 14, wherein an end of the defective-product identifying marking in a longitudinal direction of the protective film is formed in a curved shape.

16. The laminated film according to claim 14, wherein a length of the slit in a longitudinal direction of the protective film is 10 mm or more and 100 mm or less.

17. The laminated film according to claim 14, wherein a width of the slit in a width direction orthogonal to a longitudinal direction of the protective film is 2 mm or more and 40 mm or less.

18. The laminated film according to claim 1, wherein the defective-product identifying marking is a hole formed in the laminated film.

19. The laminated film according to claim 1, wherein one defective-product identifying marking is provided for one defective adhesive layer.

20. The laminated film according to claim 1, wherein a plurality of defective-product identifying markings are provided at different positions for one defective adhesive layer.

21. A method for producing the laminated film according to claim 1, the method comprising:
a preparation step of preparing a raw film including an elongated protective film, a plurality of adhesive layers provided on the protective film, and a pressure-sensitive adhesive film provided on the plurality of adhesive layers;
an inspection step of inspecting the plurality of adhesive layers of the raw film; and
a marking step of providing a defective-product identifying marking on the pressure-sensitive adhesive film at a position corresponding to a defective adhesive layer being the adhesive layer determined to be a defective product in the inspection step.
